(19) United States
(12) Patent Application Publication
(10) Pub. No.: US 2024/0196603 A1
(43) Pub. Date: Jun. 13, 2024

(54) INTEGRATED CIRCUIT DEVICE AND METHOD OF MANUFACTURING THE SAME

(71) Applicant: Samsung Electronics Co., Ltd., Suwon-si (KR)

(72) Inventors: Kwanghee CHEON, Suwon-si (KR); Hyukwoo KWON, Suwon-si (KR); Munjun KIM, Suwon-si (KR); Sungyeon KIM, Suwon-si (KR); Younseok CHOI, Suwon-si (KR)

(73) Assignee: Samsung Electronics Co., Ltd., Suwon-si (KR)

(21) Appl. No.: 18/508,445

(22) Filed: Nov. 14, 2023

(30) Foreign Application Priority Data
Dec. 13, 2022 (KR) 10-2022-0174183

(51) Int. Cl. H10B 12/00; H01L 29/423

(52) U.S. Cl. CPC H10B 12/488; H01L 29/4236; H10B 12/50

(57) ABSTRACT

An integrated circuit device includes a substrate having a plurality of active regions defined by a device isolation trench, a device isolation structure including an etching induction film and filling the device isolation trench, the etching induction film covering a bottom surface of the device isolation trench, a word line trench intersecting with the plurality of active regions and the device isolation structure and extending in a first lateral direction, a gate dielectric film covering an inner wall of the word line trench, and a word line filling a portion of the word line trench on the gate dielectric film, wherein each of the plurality of active regions includes a fin body portion under the word line and a saddle fin portion protruding from the fin body portion toward the word line, and the etching induction film is exposed by the word line trench.

### CROSS-REFERENCE TO RELATED APPLICATION

This application is based on and claims priority under 35 U.S.C. § 119 to Korean Patent Application No. 10-2022-0174183, filed on Dec. 13, 2022, in the Korean Intellectual Property Office, the disclosure of which is incorporated by reference herein in its entirety.

### BACKGROUND

The inventive concepts relate to integrated circuit (IC) devices and/or methods of manufacturing the same, and more particularly, to IC devices having a buried word line and/or methods of manufacturing the IC device.

In recent years, as the integration density of IC devices has gradually increased, a structure of an IC device having a buried channel array transistor (BCAT), in which a plurality of word lines are buried in a substrate, has been proposed. Accordingly, a vast amount of research is being conducted to improve and stabilize the operation and reliability of the BCAT.

### SUMMARY

Some example embodiments provide integrated circuit (IC) devices having improved reliability.

Some example embodiments provide methods of manufacturing an IC device with improved reliability.

According to an aspect of the inventive concepts an IC device includes a substrate having a plurality of active regions defined by a device isolation trench, a device isolation structure including an etching induction film and filling the device isolation trench, the etching induction film covering a bottom surface of the device isolation trench, a word line trench intersecting with the plurality of active regions and the device isolation structure and extending in a first lateral direction, a gate dielectric film covering an inner wall of the word line trench, and a word line filling a portion of the word line trench on the gate dielectric film, wherein each of the plurality of active regions includes a fin body portion under the word line and a saddle fin portion protruding from the fin body portion toward the word line, and at least a portion of the etching induction film is exposed by the word line trench.

According to another aspect of the inventive concepts, an IC device includes a substrate having a plurality of active regions defined by a device isolation trench, a device isolation structure including an etching induction film and filling the device isolation trench, the etching induction film covering a bottom surface of the device isolation trench, and a word line in a word line trench, the word line trench intersecting with the plurality of active regions and the device isolation structure and extending in a first lateral direction, wherein the device isolation structure has an overlap area overlapping the word line in a vertical direction, the overlap area including a first region between a first active region and a second active region adjacent to the first active region in the first lateral direction, the first active region and the second active region being selected from the plurality of active regions, and a second region between the first active region and a third active region adjacent to the first active region in the first lateral direction, the first active region and the third active region being selected from the plurality of active regions, the third active region facing the second active region with the first active region therebetween in the first lateral direction, and wherein the etching induction film is exposed through the word line trench in the first region and covers the bottom surface and a lower inner wall of the device isolation trench in the second region.

According to another aspect of the inventive concepts, an IC device includes a substrate having a cell array region, a peripheral circuit region, and an interface region between the cell array region and the peripheral circuit region, a plurality of cell active regions defined by a device isolation trench in the cell array region, a peripheral circuit active region defined by an interface trench in the peripheral circuit region, a device isolation structure including an etching induction film and filling the device isolation trench, the etching induction film covering a bottom surface of the device isolation trench in the cell array region, an interface isolation structure filling the interface trench in the peripheral circuit region, a word line trench intersecting with the plurality of cell active regions and the device isolation structure in the cell array region and extending in a first lateral direction, the word line trench having a first bottom surface exposing the plurality of cell active regions and a second bottom surface exposing the device isolation structure, a gate dielectric film covering an inner wall of the word line trench, and a word line filling a portion of the word line trench on the gate dielectric film, wherein a portion of the etching induction film is exposed through the second bottom surface.

### BRIEF DESCRIPTION OF THE DRAWINGS

Example Embodiments of the inventive concepts will be more clearly understood from the following detailed description taken in conjunction with the accompanying drawings in which:

FIG. 1 is a layout diagram of a schematic configuration of an integrated circuit (IC) device, according to an example embodiment;

FIG. 2 is an enlarged layout diagram of region “P” of FIG. 1;

FIG. 3 is an enlarged layout diagram of main components of a cell array region shown in FIG. 2;

FIG. 4 is a cross-sectional view taken along line A-A′ of FIG. 2, illustrating main components of an IC device, according to an example embodiment;

FIG. 5 is an enlarged view of region “EX1” of FIG. 4;

FIG. 6 is a cross-sectional view taken along line B-B′ of FIG. 2, illustrating main components of an IC device, according to an example embodiment;

FIG. 7 is a cross-sectional view taken along line C-C′ of FIG. 2, illustrating main components of an IC device, according to an example embodiment;

FIG. 8 is a cross-sectional view of a portion corresponding to FIG. 7, illustrating main components of an IC device, according to another example embodiment;

FIG. 9 is an enlarged cross-sectional view of portion “EX2” of FIG. 8; and

FIGS. 10A to 10J are cross-sectional views corresponding to the cross-sectional view taken along line C-C′ of FIG. 2, and illustrating a process sequence of a method of manufacturing an IC device, according to an example embodiment.

### DETAILED DESCRIPTION

Hereinafter, some example embodiments will be described in detail with reference to the accompanying drawings. The same reference numerals are used to denote the same elements in the drawings, and repeated descriptions thereof are omitted.

While the term “same,” “equal” or “identical” is used in description of example embodiments, it should be understood that some imprecisions may exist. Thus, when one element is referred to as being the same as another element, it should be understood that an element or a value is the same as another element or value within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

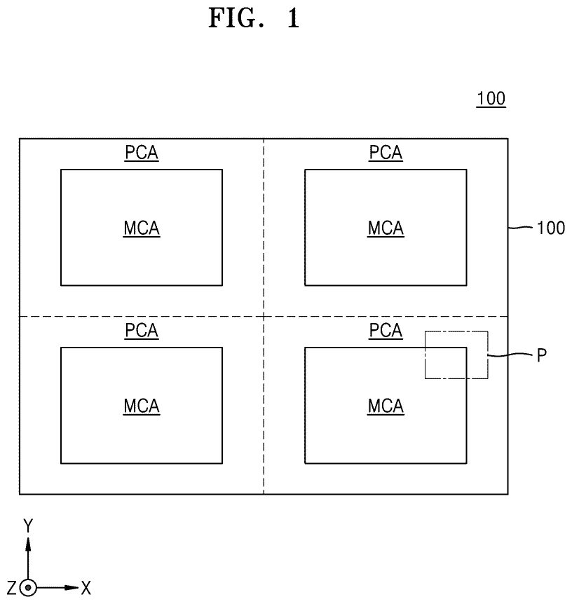

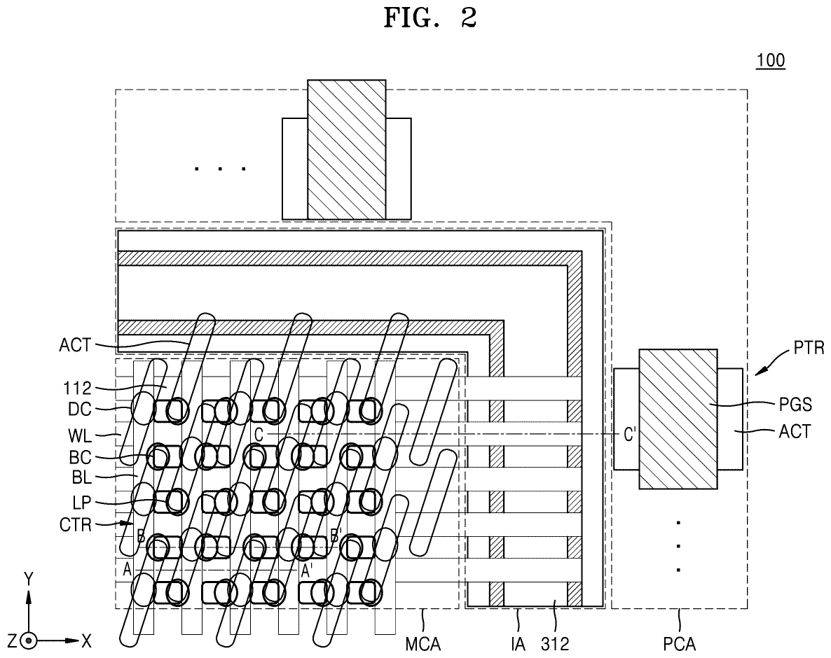

FIG. 1 is a layout diagram of a schematic configuration of an integrated circuit (IC) device 100, according to an example embodiment. FIG. 2 is an enlarged layout diagram of region “P” of FIG. 1.

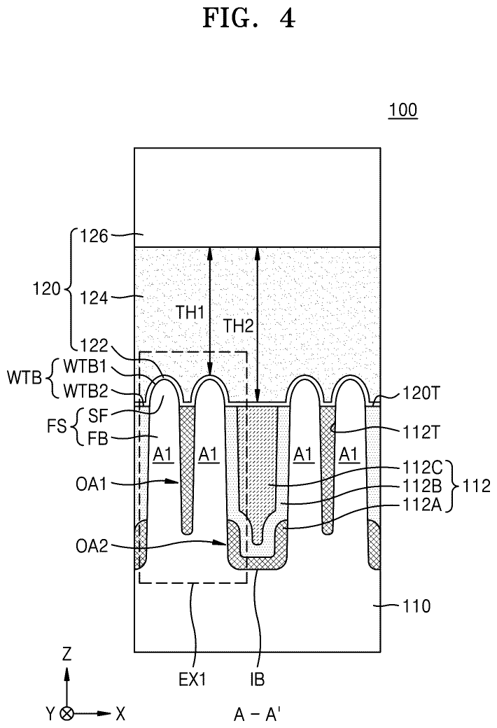

Referring to FIGS. 1 and 2, the IC device 100 may include a semiconductor substrate (refer to 110 in FIG. 4) including a cell array region MCA and a peripheral circuit region PCA. In some example embodiments, the semiconductor substrate 110 may include an interface region IA between the cell array region MCA and the peripheral circuit region PCA.

In some example embodiments, the cell array region MCA may be a memory cell region of a dynamic random access memory (DRAM) device, and the peripheral circuit region PCA may be a core region or a peripheral circuit region of the DRAM device. For example, the cell array region MCA may include a cell transistor CTR and a capacitor structure (not shown) connected thereto, and the peripheral circuit region PCA may include a peripheral circuit transistor PTR configured to transmit signals and/or power to the cell transistor CTR included in the cell array region MCA. In some example embodiments, the peripheral circuit transistor PTR may constitute various circuits, such as a command decoder, a control logic, an address buffer, a row decoder, a column decoder, a sense amplifier, and a data input/output (I/O) circuit.

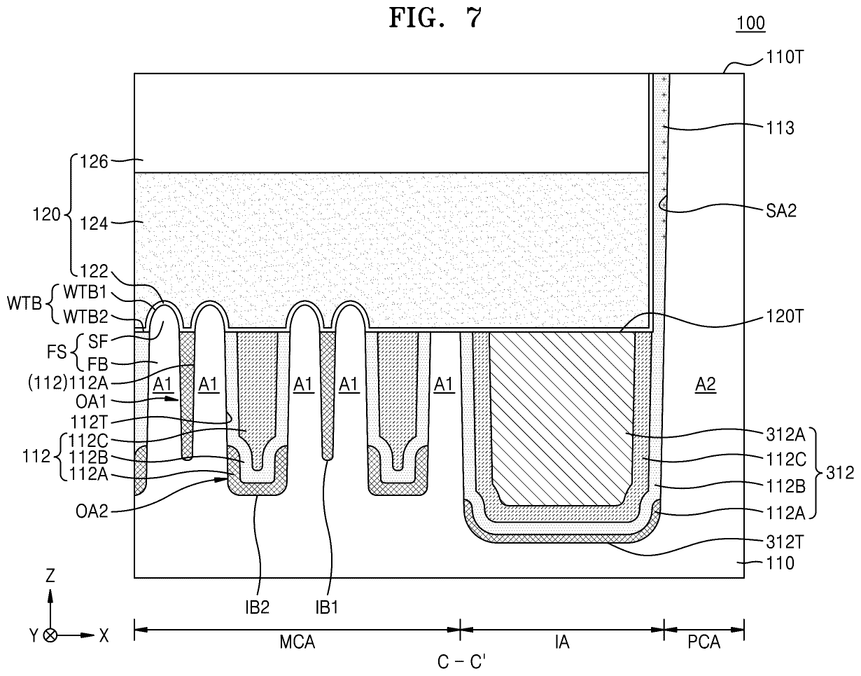

In some example embodiments, the interface region IA may include an interface isolation structure (refer to 312 in FIG. 7) configured to electrically insulate the cell array region MCA from the peripheral circuit region PCA.

In some example embodiments, the semiconductor substrate 110 may include a plurality of active regions ACT. In some example embodiments, the plurality of active regions ACT of the cell array region MCA may be defined by a device isolation structure 112 and be apart from a peripheral circuit active region ACT of the peripheral circuit region PCA with the interface isolation structure 312 therebetween.

In some example embodiments, in the cell array region MCA, each of the plurality of active regions ACT may be arranged to have a major axis in an oblique direction with respect to each of a first lateral direction (X direction) and a second lateral direction (Y direction) that intersects with the first lateral direction (X direction). In some example embodiments, the plurality of active regions ACT may be apart from each other in a lateral direction (X direction and/or Y direction).

In some example embodiments, the plurality of word lines WL may intersect with the plurality of active regions ACT and extend parallel to each other in the first lateral direction (X direction). In some example embodiments, a plurality of bit lines BL may extend parallel to each other in the second lateral direction (Y direction) on the plurality of word lines WL. The plurality of bit lines BL may be connected to the plurality of active regions ACT through direct contacts DC.

In some example embodiments, a plurality of buried contacts BC may be between two adjacent ones of the plurality of bit lines BL. In some example embodiments, the plurality of buried contacts BC may be arranged in a line in each of the first lateral direction (X direction) and the second lateral direction (Y direction). In some example embodiments, a plurality of landing pads LP may be on the plurality of buried contacts BC. In some example embodiments, each of the plurality of landing pads LP may partially overlap the buried contact BC in a vertical direction (Z direction). In some example embodiments, the plurality of buried contacts BC and the plurality of landing pads LP may be configured to connect a lower electrode (not shown) of a capacitor (not shown) formed on the plurality of bit lines BL to the active region ACT.

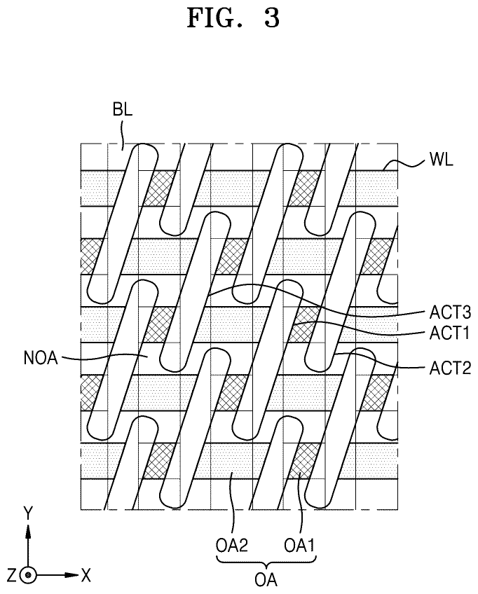

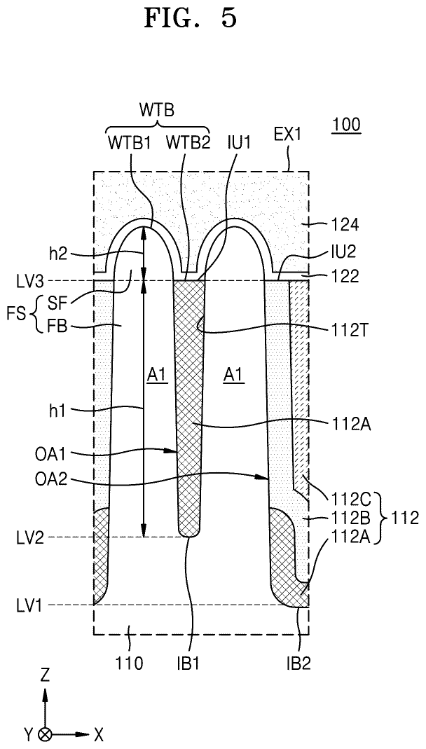

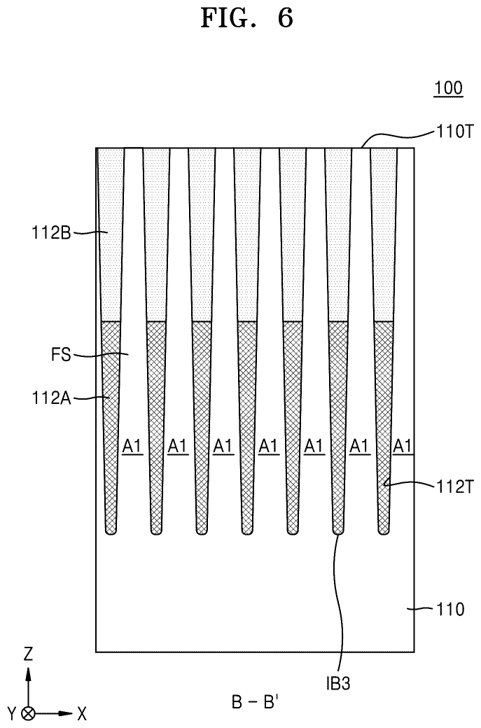

FIG. 3 is an enlarged layout diagram of main components of the cell array region MCA shown in FIG. 2. FIG. 4 is a cross-sectional view taken along line A-A′ of FIG. 2, illustrating main components of the IC device 100, according to an example embodiment. FIG. 5 is an enlarged view of region “EX1” of FIG. 4. FIG. 6 is a cross-sectional view taken along line B-B′ of FIG. 2, illustrating main components of the IC device 100, according to an example embodiment. FIG. 7 is a cross-sectional view taken along line C-C′ of FIG. 2, illustrating main components of the IC device 100, according to an example embodiment. In FIGS. 3 to 7, the illustration of the direct contact DC, the bit line BL, the buried contact BC, and the landing pad LP, which have been described with reference to FIG. 2, is omitted, but components not shown are also fully understood by one of ordinary skill in the art.

Referring to FIGS. 3 to 7, the IC device 100 may include a substrate 110 in which a plurality of cell active regions A1 and a peripheral circuit active region A2 are defined. In some example embodiments, the plurality of cell active regions A1 may be defined by a device isolation trench 112T in the cell array region MCA. In some example embodiments, the peripheral circuit active region A2 may be defined by an interface trench 312T in a peripheral circuit region PCA. The plurality of cell active regions A1 may correspond to the plurality of active regions ACT of the cell array region MCA shown in FIG. 2. Hereinafter, each of the plurality of cell active regions A1 may be referred to as a cell active region A1. The peripheral circuit active region A2 may correspond to the peripheral circuit active region ACT of the peripheral circuit region PCA shown in FIG. 2.

In some example embodiments, the substrate 110 may include silicon, for example, single crystalline silicon, polycrystalline silicon, or amorphous silicon. In other some example embodiments, the substrate 110 may include at least one selected from germanium (Ge), silicon germanium (SiGe), silicon carbide (SiC), gallium arsenide (GaAs), indium arsenide (InAs), and indium phosphide (InP). As used herein, each of the terms “SiGe,” “SiC,” “GaAs,” “InAs,” and “InP” refers to a material including elements included therein, without referring to a chemical formula representing a stoichiometric relationship, and terms described below may be understood in the same manner. In some example embodiments, the substrate 110 may include a conductive region, for example, a doped well or a doped structure.

In some example embodiments, the device isolation trench 112T may be filled by a device isolation structure 112. In some example embodiments, each of the plurality of cell active regions A1 may include a fin structure FS. For example, the device isolation structure 112 may laterally surround a plurality of fin structures FS on the substrate 110.

In some example embodiments, a plurality of word line trenches 120T may be formed in the plurality of cell active regions A1 and a plurality of device isolation structures 112. The plurality of word line trenches may intersect with the plurality of cell active regions A1 and the device isolation structure 112 and extend in a first lateral direction (X direction). In some example embodiments, the plurality of word line trenches 120T may have a plurality of line shapes extending parallel to each other in the first lateral direction (X direction).

In some example embodiments, a plurality of word line structures 120 may be inside the plurality of word line trenches 120T, respectively. For example, the plurality of word line structures 120 may be buried in the substrate 110. In some example embodiments, each of the plurality of word line structures 120 may include a gate dielectric film 122 conformally covering an inner wall of the word line trench 120T, a word line 124 filling a portion of the word line trench 120T on the gate dielectric film 122, and a buried insulating film 126 covering the word line 124 inside the word line trench 120T. In some example embodiments, the word line 124 may be at a lower vertical level than a top surface 110T of the substrate 110. In some example embodiments, the gate dielectric film 122 may conformally cover the inner wall of the word line trench 120T and surround the word line 124 and the buried insulating film 126. For example, the word line 124 may correspond to the word line WL shown in FIG. 2.

In some example embodiments, the gate dielectric film 122 may include at least one selected from silicon oxide, silicon nitride, silicon oxynitride, oxide/nitride/oxide (ONO), and a high-k dielectric film having a higher dielectric constant than silicon oxide. The high-k dielectric film may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). In some example embodiments, the word line 124 may include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. In some example embodiments, the buried insulating film 126 may include a silicon oxide film, a silicon nitride film, a silicon oxynitride film, or a combination thereof.

As shown in FIG. 3, in a view from above, the device isolation structure 112 may include an overlap area OA overlapping the word line 124 and a non-overlap area NOA that does not overlap the word line 124.

In some example embodiments, in a view from above, the overlap area OA may include a first overlap area OA1 and a second overlap area OA2, which are divided from each other based on a lateral distance between a lateral width between the plurality of active regions ACT. In some example embodiments, in a view from above, the first overlap area OA1 may be a region between a first active region ACT1 selected from the plurality of active regions ACT and a second active region ACT2, which is selected from the plurality of active regions ACT and adjacent to the first active region ACT1 in the first lateral direction (X direction). For example, the first overlap area OA1 may be a region between two active regions ACT, which are selected from the plurality of active regions ACT in the overlap area OA and are most adjacent to each other in the first lateral direction (X direction). In some example embodiments, in a view from above, the second overlap area OA2 may be a region between a third active region ACT3 and the first active region ACT1. The third active region ACT3 may be selected from the plurality of active regions ACT and face the second active region ACT2 in the first lateral direction (X direction) with the first active region ACT1 therebetween. For example, the second overlap area OA2 may be a region apart from the first overlap area OA1 in the first lateral direction (X direction) with an arbitrary active region ACT of the overlap area OA therebetween. In some example embodiments, the first overlap areas OA1 and the second overlap areas OA2 may be alternately arranged in the first lateral direction (X direction).

In some example embodiments, in a view from above, a bottom surface IB of the device isolation structure 112 may have a different vertical level according to regions. As used herein, the term “level” may refer to a height in a vertical direction (Z direction). In some example embodiments, in a view from above, a vertical level of the bottom surface IB of the device isolation structure 112 according to a region may vary according to a lateral distance between the plurality of cell active regions A1.

In some example embodiments, a width of the device isolation structure 112 of the first overlap area OA1 in the first lateral direction (X direction) may be less than a width of the device isolation structure 112 of the second overlap area OA2 in the first lateral direction (X direction). In some example embodiments, the device isolation structure 112 may have a first structure bottom surface IB1 in the first overlap area OA1, and the device isolation structure 112 may have a second structure bottom surface IB2 in the second overlap area OA2. According to some example embodiments, a vertical level of the first structure bottom surface IB1 may be higher than a vertical level of the second structure bottom surface IB2. For example, the second structure bottom surface IB2 may have a first vertical level LV1, and the first structure bottom surface IB1 may have a second vertical level LV2 that is higher than the first vertical level LV1.

In some example embodiments, in the non-overlap area NOA, the device isolation structure 112 may have a third structure bottom surface IB3. In some example embodiments, the third structure bottom surface IB3 may have the same or substantially similar vertical level as the first structure bottom surface IB1, without being limited thereto. In some example embodiments, the third structure bottom surface IB3 may have a vertical level that is higher than the first structure bottom surface IB1. In some other example embodiments, the third structure bottom surface IB3 may have a vertical level that is lower than the first structure bottom surface IB1. In still other example embodiments, the third structure bottom surface IB3 may include a portion having a higher vertical level than the first structure bottom surface IB1 and a portion having a lower vertical level than the first structure bottom surface IB1.

In some example embodiments, a bottom surface WTB of the word line trench 120T may include a first word line trench bottom WTB1 at which the cell active region A1 of the substrate 110 is exposed, and a second word line trench bottom WTB2 at which the device isolation structure 112 is exposed. In some example embodiments, the first word line trench bottom WTB1 (e.g., a top of the first word line trench bottom WTB1) may have a higher vertical level than the second word line trench bottom WTB2 (e.g., a top of the second word line trench bottom WTB2). In some example embodiments, a first thickness TH1, which is a thickness of the word line 124 in the vertical direction (Z direction) on the first word line trench bottom WTB1, may be smaller than a second thickness TH2, which is a thickness of the word line 124 in the vertical direction (Z direction) on the second word line trench bottom WTB2. For example, the first thickness TH1 may be a thickness of the word line 124 in the vertical direction (Z direction) on a bottom surface of the first word line trench bottom WTB1, which is at a highest vertical level of the bottom surface WTB of the word line trench 120T.

In some example embodiments, through the second word line trench bottom WTB2, a first structure top surface IU1 of the device isolation structure 112 may be exposed in the first overlap area OA1, and a second structure top surface IU2 of the device isolation structure 112 may be exposed in the second overlap area OA2. In some example embodiments, the second structure top surface IU2 may have a third vertical level LV3 that is higher than the second vertical level LV2. In some example embodiments, the first structure top surface IU1 may have the same vertical level as the second structure top surface IU2. For example, each of the first structure top surface IU1 and the second structure top surface IU2 may have the third vertical level LV3.

In some example embodiments, a bottom surface of the word line 124 may have a concavo-convex shape corresponding to a profile of the bottom surface WTB of the word line trench 120T, and a saddle fin field-effect transistor (FinFET) structure may be formed on the plurality of cell active regions A1. In some example embodiments, in the overlap area OA, the fin structure FS of the cell active region A1 may include a fin body portion FB and a saddle fin portion SF. The fin body portion FB may be surrounded by the device isolation structure 112. The saddle fin portion SF may be integrally connected to the fin body portion FB and protrude from the fin body portion FB toward the word line 124 in the vertical direction (Z direction).

In some example embodiments, the gate dielectric film 122 may cover an inner surface of the word line trench 120T to contact the plurality of cell active regions A1 and the device isolation structures 112. In some example embodiments, the gate dielectric film 122 may cover a top surface of the saddle fin portion SF, the first structure top surface IU1 of the device isolation structure 112, and the second structure top surface IU2 of the device isolation structure 112. In some example embodiments, the top surface of the saddle fin portion SF, the first structure top surface IU1, and the second structure top surface IU2 may face the word line 124 with the gate dielectric film 122 therebetween.

In some example embodiments, in the overlap area OA, the fin body portion FB of the fin structure FS may have a first height h1, which is a height obtained in the vertical direction (Z direction), and the second fin portion SF of the fin structure FS may have a second height h2, which is a height obtained in the vertical direction (Z direction). In some example embodiments, the first height h1 of the fin body portion FB may correspond to a difference in vertical level between the first structure bottom surface IB1 of the device isolation structure 112 in the first overlap area OA1 and the first structure top surface IU1 of the device isolation structure 112 in the first overlap area OA1. In some example embodiments, the second height h2 of the saddle fin portion SF may correspond to a length of a portion of the fin structure FS, which protrudes from the first structure top surface IU1 of the device isolation structure 112 toward the word line 124 in the first overlap area OA1, in the vertical direction (Z direction).

In some example embodiments, a ratio of the second height h2 of the saddle fin portion SF to the first height h1 of the fin body portion FB may be about 0.2 or higher. In some example embodiments, a ratio of the second height h2 to the first height h1 may be in a range of about 0.2 to about 1.5. In some example embodiments, a ratio of the second height h2 to the first height h1 may be in a range of about 0.5 to about 1.5. In some example embodiments, a ratio of the second height h2 to the first height h1 may be in a range of about 0.7 to about 1. Because the IC device 100 according to some example embodiments includes the saddle fin portion SF protruding in the vertical direction (Z direction), an area of the cell active region A1 overlapping the word line 124 may be increased. Thus, the electrical properties of the IC device 100 may be improved.

In some example embodiments, the device isolation structure 112 may include an etching induction film 112A, an insulating liner 112B, a gap-fill insulating film 112C. In some example embodiments, the etching induction film 112A may cover a bottom surface of the device isolation trench 112T.

In some example embodiments, in a view from above, the device isolation structure 112 may be configured differently according to regions. In some example embodiments, in the first overlap area OA1, the device isolation structure 112 may include the etching induction film 112A. In some example embodiments, in the first overlap area OA1, the etching induction film 112A may entirely cover the bottom surface and the inner wall of the device isolation trench 112T and fill the device isolation trench 112T, and a top surface of the etching induction film 112A may be exposed by the word line trench 120T. In this case, in the first overlap area OA1, the first structure top surface IU1 may be a top surface of the etching induction film 112A in the first overlap area OA1. In some example embodiments, the etching induction film 112A of the first overlap area OA1 may face the word line 124 with the gate dielectric film 122 therebetween.

In some example embodiments, the etching induction film 112A may include a material having a higher etch rate than the insulating liner 112B during an etching process for forming the word line trench 120T. In some example embodiments, the etching induction film 112A may include silicon oxide doped with fluorine (F). For example, the etching induction film 112A may include oxygen (O), fluorine (F), and balance of silicon (Si).

In some example embodiments, the etching induction film 112A may have a first oxygen content, which may be about 66 at % or less, based on the total element content of the etching induction film 112A. For example, the first oxygen content may be in a range of about 30 at % to about 66 at %, based on the total element content of the etching induction film 112A. In some example embodiments, the first oxygen content may be in a range of about 40 at % to about 60 at %, based on the total element content of the etching induction film 112A. In some example embodiments, the first oxygen content may be in a range of about 45 at % to about 50 at %, based on the total element content of the etching induction film 112A.

In some example embodiments, the etching induction film 112A may have a first fluorine content, which may be about 20 at % or less, based on the total element content of the etching induction film 112A. For example, the first fluorine content may be in a range of about 0.01 at % to about 20 at %, based on the total element content of the etching induction film 112A. In some example embodiments, the first fluorine content may be in a range of about 0.01 at % to about 14 at %, based on the total element content of the etching induction film 112A. In some example embodiments the first fluorine content may be in a range of about 0.01 at % to about 10 at %, based on the total element content of the etching induction film 112A. In some example embodiments, the first fluorine content may be in a range of about 0.5 at % to about 10 at %, based on the total element content of the etching induction film 112A. As used herein, “at %” may refer to an atomic percent.

In some example embodiments, in the second overlap area OA2, the device isolation structure 112 may include an etching induction film 112A, an insulating liner 112B, and a gap-fill insulating film 112C. In some example embodiments, in the second overlap area OA2, the etching induction film 112A may cover a bottom surface IB of the device isolation trench 112T and a portion of the inner wall of the device isolation trench 112T, which is adjacent to the bottom surface IB. For example, the etching induction film 112A may cover the bottom surface IB and a lower inner wall of the device isolation trench 112T without covering an upper inner wall thereof. In some example embodiments, the insulating liner 112B covering the top surface of the etching induction film 112A and the exposed inner wall of the device isolation trench 112T may be on the etching induction film 112A. In some example embodiments, the gap-fill insulating film 112C filling a space defined by the insulating liner 112B may be inside the device isolation trench 112T. In some example embodiments, in the second overlap area OA2, the etching induction film 112A may not be exposed by the word line trench 120T. For example, in the second overlap area OA2, the insulating liner 112B and the gap-fill insulating film 112C may be exposed through the word line trench 120T.

In some example embodiments, each of the insulating liner 112B and the gap-fill insulating film 112C may include a silicon oxide film, a silicon nitride film, or a silicon oxynitride film. For example, the insulating liner 112B may include a silicon oxide film, and the gap-fill insulating film 112C may include a silicon nitride film.

In some example embodiments, in the non-overlap area NOA, the device isolation structure 112 may include the etching induction film 112A and the insulating liner 112B. In some example embodiments, in the non-overlap area NOA, the etching induction film 112A may fill a lower portion of the device isolation trench 112T. For example, the top surface of the etching induction film 112A may be at a lower vertical level than the top surface 110T of the substrate 110. In some example embodiments, in the non-overlap area NOA, the insulating liner 112B filling the device isolation trench 112T may be on the etching induction film 112A. For example, a top surface of the insulating liner 112B may be at the same or substantially similar vertical level as the top surface 110T of the substrate 110.

In some example embodiments, an interface isolation structure 312 may be inside the interface trench 312T of the interface region IA. In some example embodiments, the interface isolation structure 312 may include an etching induction film 112A, an insulating liner 112B, a gap-fill insulating film 112C, and an interface insulating film 312A. In some example embodiments, the etching induction film 112A may be on a bottom surface of the interface trench 312T. For example, the etching induction film 112A may cover a portion of an inner wall of the interface trench 312T, which is adjacent to the bottom surface of the interface trench 312T. In some example embodiments, in the interface region IA, the insulating liner 112B, the gap-fill insulating film 112C, and the interface insulating film 312A may be sequentially on the etching induction film 112A. For example, the insulating liner 112B may conformally cover the top surface of the etching induction film 112A and the exposed inner wall of the interface trench 312T on the etching induction film 112A. The gap-fill insulating film 112C may conformally cover the top surface of the insulating liner 112B, and the interface insulating film 312A may fill a space defined by the gap-fill insulating film 112C inside the interface trench 312T.

In some example embodiments, at a boundary between the interface region IA and the peripheral circuit region PCA, the insulating liner 112B may be between the peripheral circuit active region A2 and the gate dielectric film 122. In some example embodiments, a deposition inhibition film 113 may be between a portion of the insulating liner 112B, which covers an upper sidewall of the peripheral circuit active region A2 exposed by the interface trench 312T, and the peripheral circuit active region A2. In some example embodiments, the deposition inhibition film 113 may cover the upper sidewall of the peripheral circuit active region A2. For example, the deposition inhibition film 113 may have a smaller thickness than the insulating liner 112B. In some example embodiments, the deposition inhibition film 113 may include nitrogen (N₂), nitrogen trifluoride (NF₃), ammonia (NH₃) or a combination thereof.

In some example embodiments, the interface insulating film 312A may include a silicon oxide film. In some example embodiments, the silicon oxide film included in the interface insulating film 312A may include tonen silazene (TOSZ), a high-density plasma (HDP) oxide film, or an undoped silicate glass (USG) oxide film. In some other example embodiments, an oxide film included in the interface insulating film 312A may be a spin-on-glass (SOG) oxide film, which includes silicate, siloxane, methyl silsesquioxane (MSQ), hydrogen silsesquioxane (HSQ), polysilazane, or a combination thereof.

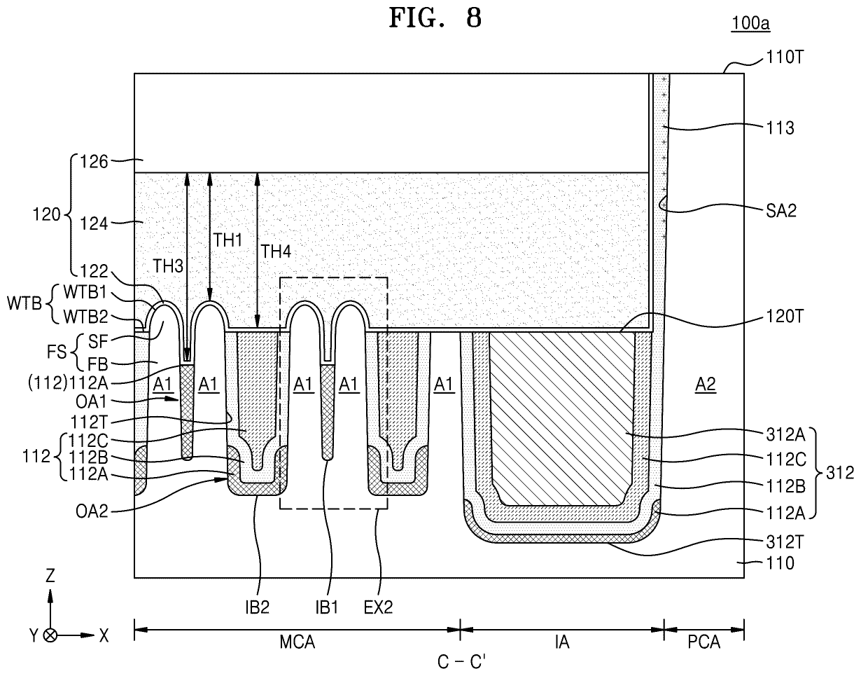

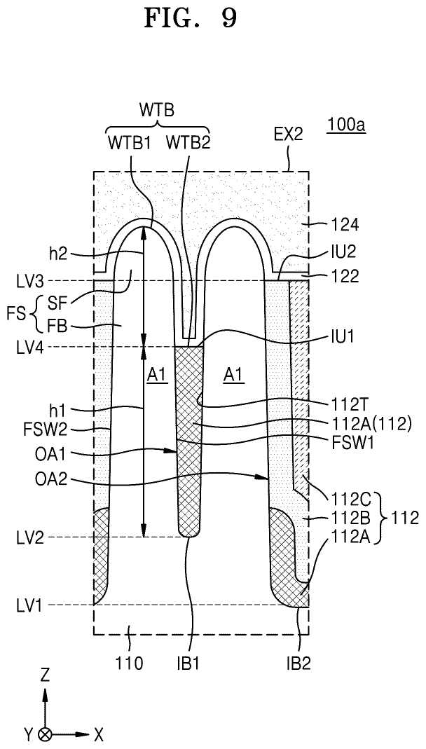

FIG. 8 is a cross-sectional view of a portion corresponding to FIG. 7, illustrating main components of an IC device 100a, according to an example embodiment. FIG. 9 is an enlarged cross-sectional view of portion “EX2” of FIG. 8, illustrating main components of the IC device 100a, according to an example embodiment. Differently from FIG. 7, in FIG. 8, a vertical level of a first structure top surface IU1 of a device isolation structure 112 in a first overlap area OA1 may be different from a vertical level of a second structure top surface IU2 of the device isolation structure 112 in a second overlap area OA2.

Referring to FIGS. 8 and 9, the first structure top surface IU1 of the device isolation structure 112 in the first overlap area OA1 may be at a lower level than the second structure top surface IU2 of the device isolation structure 112 in the second overlap area OA2 in a vertical direction (Z direction). In some example embodiments, the second structure top surface IU2 of the device isolation structure 112 may have a third vertical level LV3 in the second overlap area OA2, and the first structure top surface IU1 of the device isolation structure 112 may have a fourth vertical level LV4 in the first overlap area OA1. The fourth vertical level LV4 may be lower than the third vertical level LV3

In some example embodiments, a third thickness TH3, which is a thickness of a word line 124 on the first structure top surface IU1, may be greater than a fourth thickness TH4, which is a thickness of the word line 124 on the second structure top surface IU2. In some example embodiments, the fourth thickness TH4 may be greater than a first thickness TH1, which is a thickness of the word line 124 on an uppermost surface of a saddle fin portion SF.

In some example embodiments, the fin structure FS of the cell active region A1 may have a first sidewall FSW1 facing the device isolation structure 112 of the first overlap area OA1 and a second sidewall FSW2 facing the device isolation structure 112 of the second overlap area OA2. In some example embodiments, an area of a first portion of the first sidewall FSW1, which is exposed by the word line trench 120T, may be greater than an area of a second portion of the second sidewall FSW2, which is exposed by the word line trench 120T. In some example embodiments, the first portion and the second portion may constitute a top surface of the saddle fin portion SF. The first portion and the second portion may be exposed through the first word line trench bottom WTB1 and face the word line 124 with a gate dielectric film 122 therebetween.

In some example embodiments, because the first structure top surface IU1 of the device isolation structure 112 is at the fourth vertical level LV4 that is lower than the third vertical level LV3 in the first overlap area OA1, a ratio of the second height h2 of the saddle fin portion SF to the first height h1 of the fin body portion FB may be further increased.

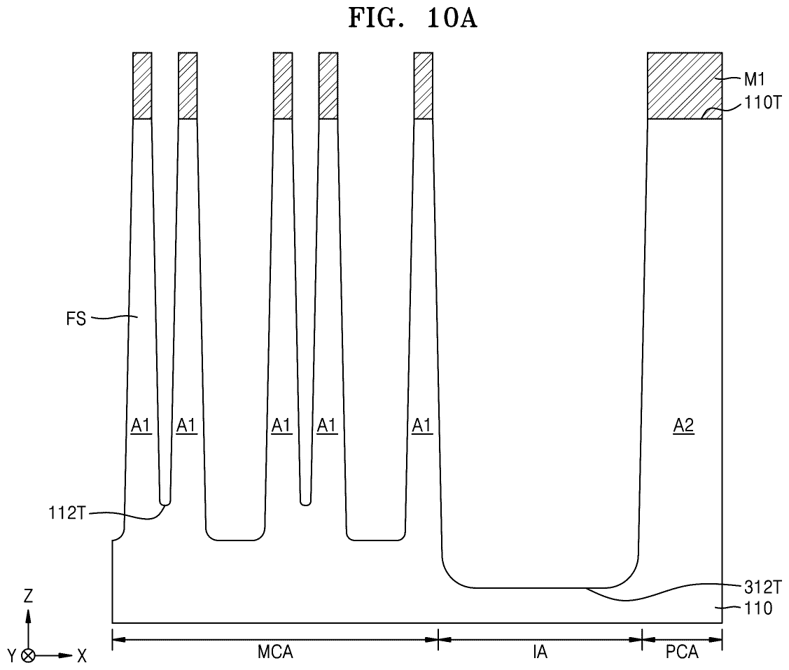

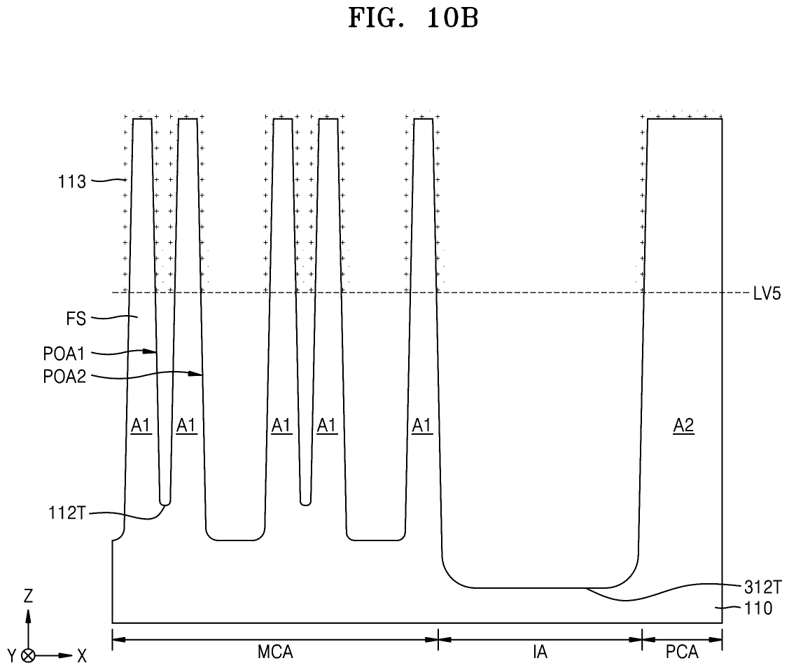

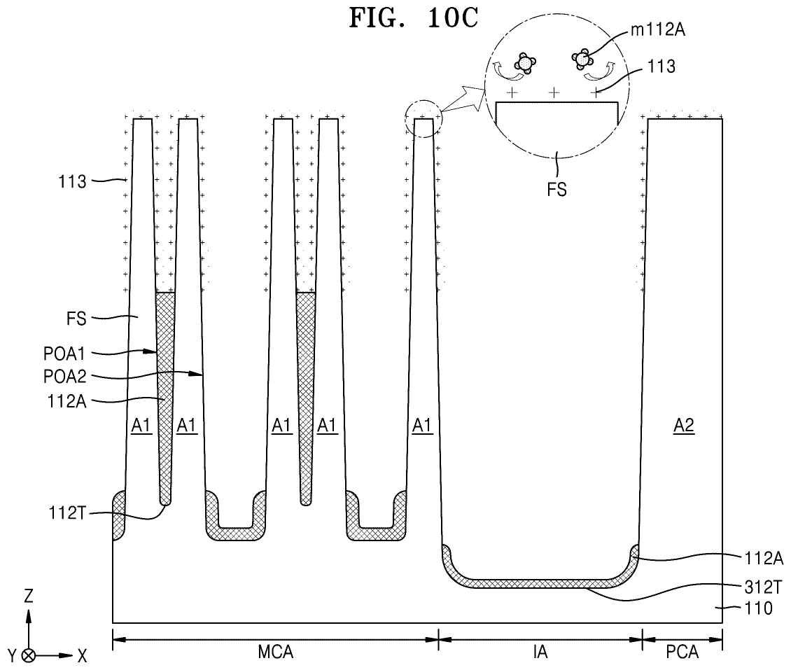

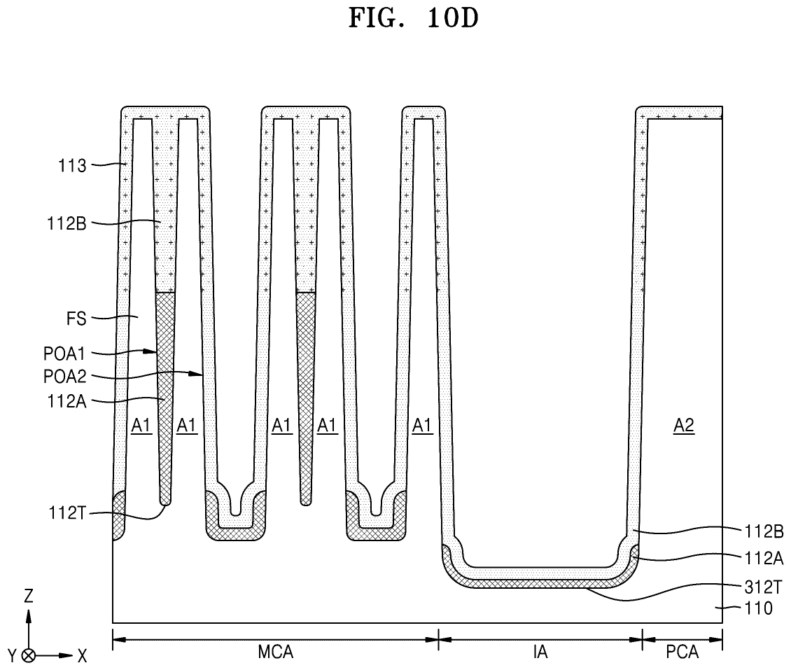

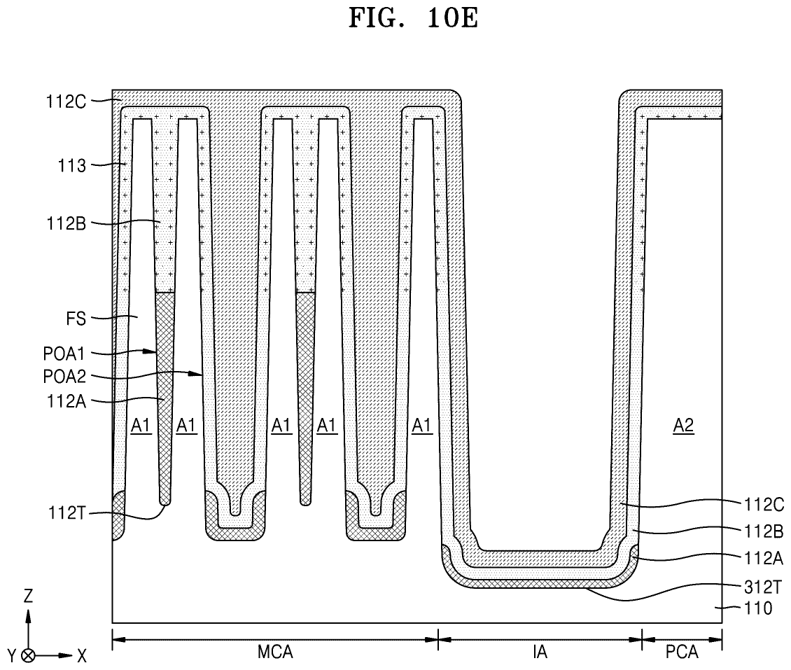

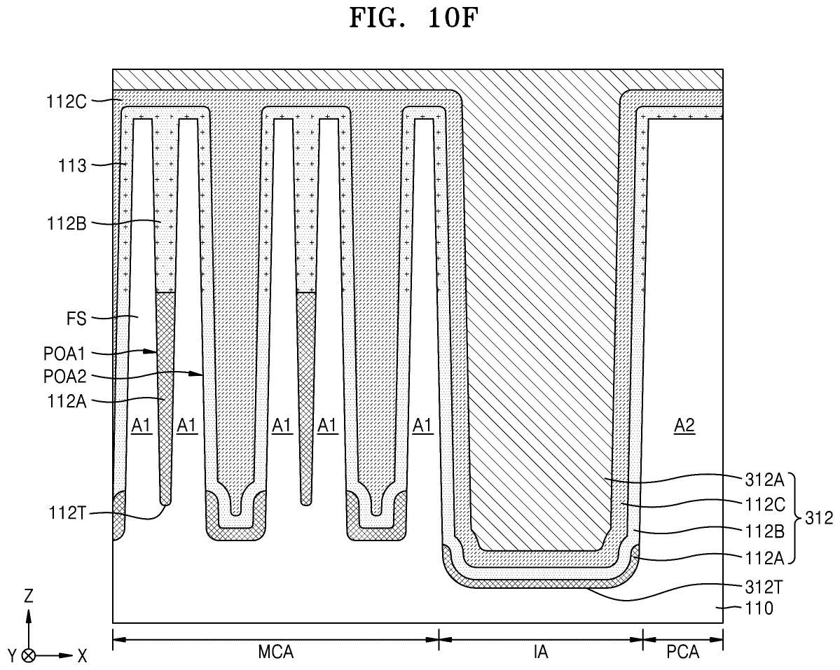

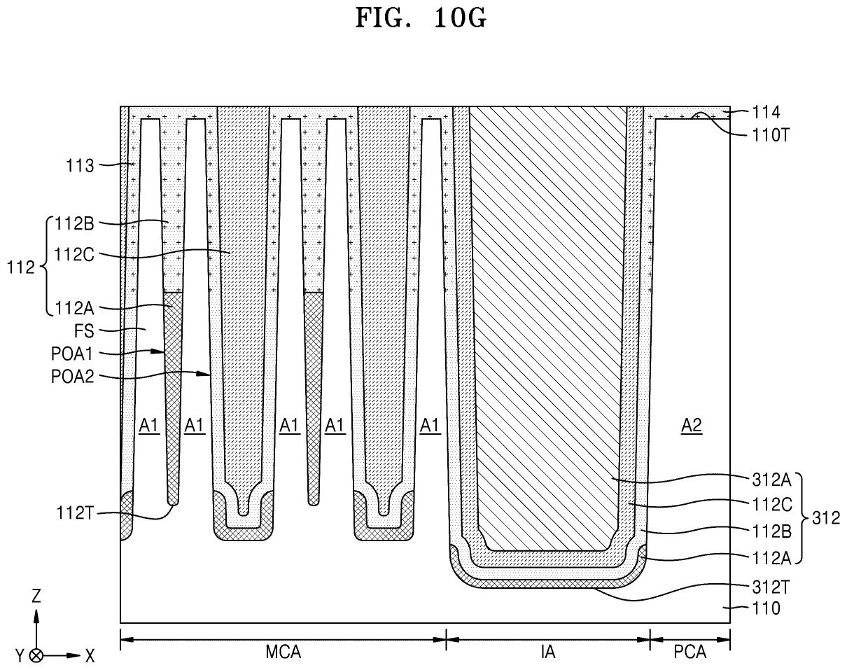

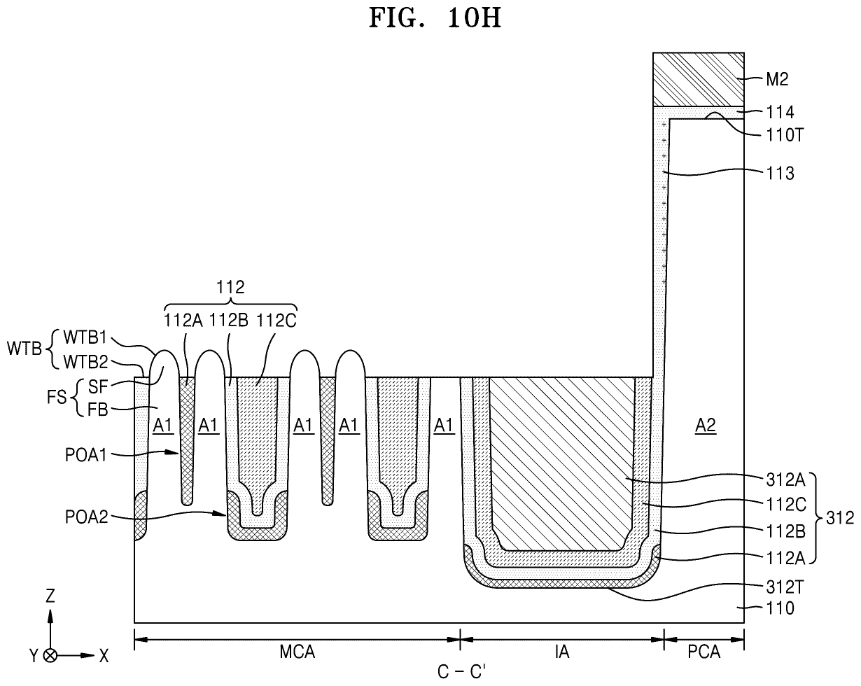

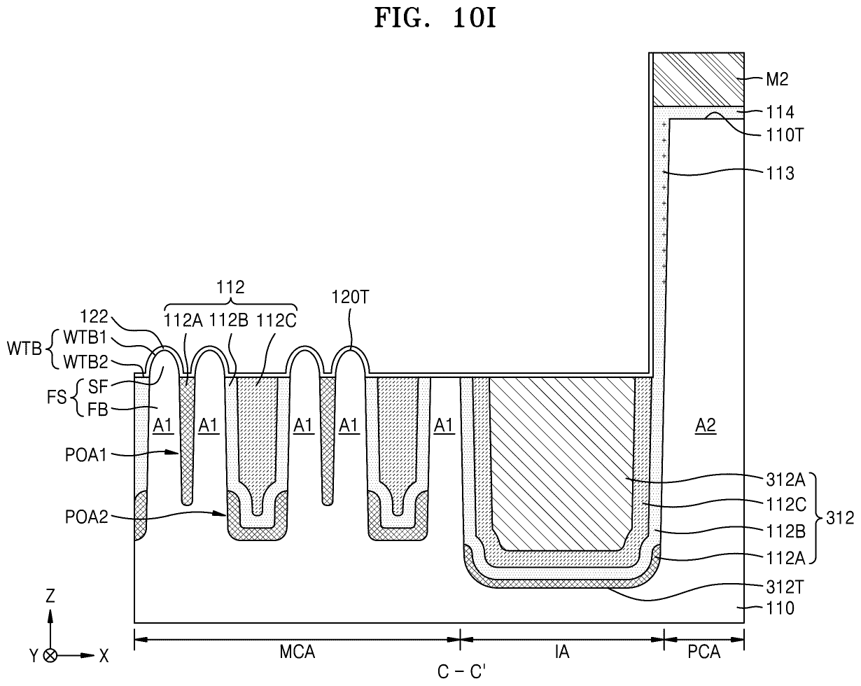

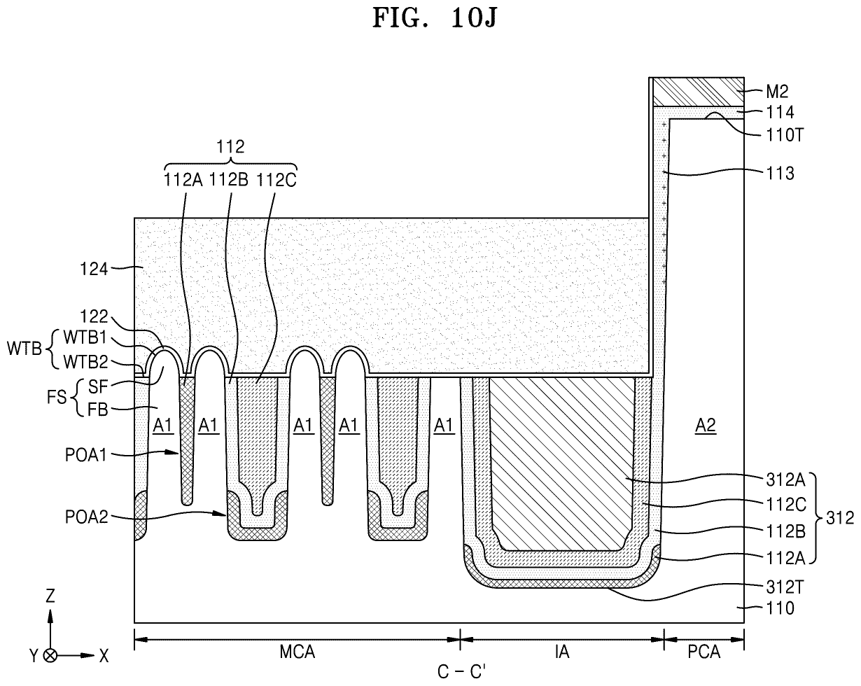

FIGS. 10A to 10J are cross-sectional views corresponding to the cross-sectional view taken along line C-C′ of FIG. 2, illustrating a process sequence of a method of manufacturing an IC device 100, according to an example embodiment. Hereinafter, as an example, a method of manufacturing the IC device 100 shown in FIGS. 2 to 7 is described with reference to FIGS. 10A to 10J.

Referring to FIG. 10A, a substrate 110 having a cell array region MCA, a peripheral circuit region PCA, and an interface region IA therebetween may be prepared.

In some example embodiments, a first mask pattern M1 may be formed on the substrate 110 to cover a portion of the cell array region MCA and the peripheral circuit region PCA. Thereafter, the substrate 110 may be etched by using the first mask pattern M1 as an etch mask, and thus, a device isolation trench 112T may be formed in the cell array region MCA, and an interface trench 312T may be formed in the interface region IA. For example, a plurality of cell active regions A1 in the cell array region MCA and a peripheral active region A2 in the peripheral circuit region PCA may be defined by the device isolation trench 112T and the interface trench 312T. In some example embodiments, the first mask pattern M1 may include a hardmask, which includes an oxide film, polysilicon, or a combination thereof.

Referring to FIG. 10B, in the resultant structure of FIG. 10A, after the first mask pattern M1 is removed, a deposition inhibition film 113 may be formed to cover upper portions of the plurality of cell active regions A1 and an upper portion of the peripheral circuit active region A2. In some example embodiments, the deposition inhibition film 113 may be formed by using a plasma process. In some example embodiments, the deposition inhibition film 113 may cover a top surface and an upper sidewall of a fin structure FS of each of the plurality of cell active regions A1 and cover a top surface and an upper sidewall of the peripheral circuit active region A2. For example, the deposition inhibition film 113 may not cover a bottom surface and a lower inner wall of the device isolation trench 112T and may not cover a bottom surface and a lower inner wall of the interface trench 312T. For example, the deposition inhibition film 113 may cover the fin structure FS of each of the plurality of cell active regions A1 and a portion of an exposed surface of the peripheral circuit active region A2, at a level higher than a fifth vertical level LV5. For example, the fifth vertical level LV5 may be higher than a level of the bottom surface of each of the device isolation trench 112T and the interface trench 312T and lower than a level of a top surface 110T of the substrate 110. In some example embodiments, the deposition inhibition film 113 may include nitrogen (N₂), nitrogen trifluoride (NF₃), ammonia (NH₃), or a combination thereof.

Referring to FIGS. 10B and 10C, in the resultant structure of FIG. 10B, an etching induction film 112A may be formed on the bottom surface of each of the device isolation trench 112T and the interface trench 312T. In some example embodiments, the etching induction film 112A may be formed on a portion, which is not covered by the deposition inhibition film 113, of a surface of each of the device isolation trench 112T and the interface trench 312T. For example, because the deposition inhibition film 113 covers the top surface and the upper sidewall of each of the plurality of cell active regions A1 and the peripheral circuit active region A2, the deposition inhibition film 113 may inhibit the deposition of an etching induction film precursor m112A during the process of forming the etching induction film 112A. Accordingly, the etching induction film 112A may cover the bottom surface and the lower inner wall of each of the device isolation trench 112T and the interface trench 312T. For example, the etching induction film 112A may not cover the top surface and the upper sidewall of each of the plurality of cell active regions A1 and the peripheral circuit active region A2.

In some example embodiments, the cell array region MCA may include a first preliminary overlap area POA1 and a second preliminary overlap area POA2. For example, the first preliminary overlap area POA1 may be a portion corresponding to the first overlap area OA1 described with reference to FIG. 3, and the second preliminary overlap area POA2 may be a portion corresponding to the second overlap area OA2 described with reference to FIG. 3.

In some example embodiments, in the first preliminary overlap area POA1, the etching induction film 112A may fill a portion of the device isolation trench 112T to a level equal to or lower than the fifth vertical level LV5. In some example embodiments, in the second preliminary overlap area POA2, the etching induction film 112A may cover the bottom surface and a portion of the lower inner wall of the device isolation trench 112T. For example, the bottom surface of the device isolation trench 112T in the second preliminary overlap area POA2 may have a greater width than the bottom surface of the device isolation trench 112T in the first preliminary overlap area POA1 in a first lateral direction (X direction). For example, in the second preliminary overlap area POA2, the etching induction film 112A may conformally cover the bottom surface of the device isolation trench 112T and the lower inner wall of the device isolation trench 112T to a lower vertical level than the fifth vertical level LV5. In some example embodiments, in the interface region IA, the etching induction film 112A may cover the bottom surface of the interface trench 312T and the lower inner wall of the interface trench 312T to a lower vertical level than the fifth vertical level LV5.

Referring to FIGS. 10D to 10F, in the resultant structure of FIG. 10C, an insulating liner 112B may be formed on the etching induction film 112A. In some example embodiments, the insulating liner 112B may cover a top surface of the etching induction film 112A and the inner wall of each of the device isolation trench 112T and the interface trench 312T. In this case, the insulating liner 112B may cover the deposition inhibition film 113, which covers an upper portion of each of the device isolation trench 112T and the interface trench 312T. In some example embodiments, a portion of the insulating liner 112B, which covers the etching induction film 112A, may have a greater thickness than a portion of the insulating liner 112B, which covers the deposition inhibition film 113. In some example embodiments, the insulating liner 112B may cover a top surface of the etching induction film 112A and fill the remaining portion of the device isolation trench 112T in the first preliminary overlap area POA1. In some example embodiments, the insulating liner 112B may cover a top surface of the etching induction film 112A and an exposed inner wall of the device isolation trench 112T in the second preliminary overlap area POA2. In some example embodiments, the insulating liner 112B may cover a top surface of the etching induction film 112A and an exposed inner wall of the interface trench 312T in the interface region IA. Thereafter, a gap-fill insulating film 112C may be formed on the insulating liner 112B. In some example embodiments, in the second preliminary overlap area POA2, the gap-fill insulating film 112C may fill a space defined by the insulating liner 112B inside the device isolation trench 112T. In some example embodiments, the gap-fill insulating film 112C may cover a top surface of the insulating liner 112B, which is exposed in the interface region IA, and fill a portion of the interface trench 312T. Thereafter, an interface insulating film 312A may be formed on the gap-fill insulating film 112C. In some example embodiments, the interface insulating film 312A may be formed at a higher level than the top surface 110T of the substrate 110 in the cell array region MCA. In some example embodiments, the interface insulating film 312A may fill a space defined by the gap-fill insulating film 112C inside the interface trench 312T. In some example embodiments, each of the insulating liner 112B, the gap-fill insulating film 112C, and the interface insulating film 312A may be formed by using an atomic layer deposition (ALD) process.

Referring to FIG. 10G, in the resultant structure of FIG. 10F, the insulating liner 112B, the gap-fill insulating film 112C, and the interface insulating film 312A on the top surface 110T of the substrate 110 may be partially removed by using an etching process. In some example embodiments, to form a device isolation structure 112 and an interface isolation structure 312, an insulating thin film 114, which is a portion of the insulating films (e.g., 112B, 112C, and 132A) covering the top surface 110T of the substrate 110, may remain covering the top surface 110T of the substrate 110. For example, the insulating thin film 114 may protect a surface of the substrate 110 during a subsequent ion implantation process for implanting impurity ions into the substrate 110 or during a subsequent etching process.

Referring to FIG. 10H, in the resultant structure of FIG. 10G, a portion of the substrate 110, a portion of the device isolation structure 112, and a portion of the interface isolation structure 312 may be etched by using a second mask pattern M2 as an etch mask. Thus, a word line trench 120T extending in the first lateral direction (X direction) may be formed across the plurality of cell active regions A1, the device isolation structure 112, and the interface isolation structure 312. In some example embodiments, the second mask pattern M2 may include an oxide film, an amorphous carbon layer (ACL), a SiON film, or a combination thereof. During the formation of the word line trench 120T, a saddle fin portion SF protruding from a bottom surface WTB of the word line trench 120T may be formed due to a difference in etch rate between the substrate 110 and the device isolation structure 112.

In some example embodiments, during the etching process for forming the word line trench 120T, the substrate 110, the device isolation structure 112, and the interface isolation structure 312 may be etched under a condition that an etch rate of the etching induction film 112A is higher than etch rates of the insulating liner 112B, the gap-fill insulating film 112C, and the interface insulating film 312A. For example, the device isolation structure 112 and the interface isolation structure 312 may be etched at the same etch rate or substantially similar etch rates from the top surface 110T of the substrate 110 to the fifth vertical level (refer to LV5 in FIG. 10B). During the process of etching the device isolation structure 112, the etching induction film 112A may be exposed in the first preliminary overlap area POA1. The etching induction film 112A in the first preliminary overlap area POA1 may be etched at a higher etch rate than the device isolation structure 112 (e.g., the insulating liner 112B, the gap-fill insulating film 112C, and the interface insulating film 312A) in the second preliminary overlap area POA2. Accordingly, an area of the saddle fin portion SF exposed through the word line trench 120T may be further increased. For example, the first preliminary overlap area POA1 may have a less horizontal width than the second preliminary overlap area POA1, and accordingly, the insulating layer 112 of the first preliminary overlap area POA1 may be relatively difficult to etch. However, the etch inducing film 112A of the first preliminary overlap area POA1 may be etched at a relatively high etch rate, and thus, the second word line trench bottom WTB2 of the first overlap area OA1 and the second word line trench bottom WTB2 of the second overlap area OA2 may be formed to be at the same vertical level or a substantially similar vertical level. In some other example embodiments, the etching induction film 112A of the first preliminary overlap area POA1 may be etched at a relatively high rate, and thus, the second word line trench bottom WTB2 of the first overlap area OA1 may be formed to be at a lower vertical level than the second word line trench bottom WTB2 of the second overlap area OA2. For example, a top surface of the device isolation structure 112 in the first overlap area OA1 (e.g., the first structure top surface (refer to IU1 in FIG. 9)) may be formed to be at a lower vertical level than a top surface of the device isolation structure 112 in the second overlap area OA2 (e.g., the second structure top surface (refer to IU2 in FIG. 9)). Thereafter, an IC device 100a may be formed by performing processes described below. For example, the deposition inhibition film 113 of the cell array region MCA may be removed together with an upper portion of the fin structure FS during the etching process for forming the word line trench 120T. For example, the deposition inhibition film 113 may remain on the upper sidewall of the peripheral circuit active region A2 of the peripheral circuit region PCA.

Referring to FIG. 10I, a gate dielectric film 122 conformally covering an inner wall of the word line trench 120T may be formed on the resultant structure of FIG. 10H. For example, the gate dielectric film 122 may be formed by using an ALD process.

Referring to FIG. 10J, a conductive layer (not shown) filling the word line trench 120T may be formed on the gate dielectric film 122. Thereafter, the conductive layer may be etched back, and thus, a word line 124 filling a portion of the word line trench 120T may be formed from the conductive layer.

In some example embodiments, the conductive layer may have a structure in which a metal-containing liner and a metal film are sequentially stacked. The metal-containing liner may be in contact with the gate dielectric film 122. The metal film may be apart from the gate dielectric film 122 and surround the metal-containing liner. In some example embodiments, the metal-containing liner may include titanium nitride (TiN), and the metal film may include tungsten (W), without being limited thereto.

While the conductive layer is being etched back to form the word line 124, the second mask pattern M2 may be partially consumed, and thus, a thickness of the second mask pattern M2 may be reduced.

Referring to FIGS. 10J and 9 together, in the resultant structure of FIG. 10J, a space remaining on the word line 124 in an inner space of the word line trench 120T may be filled by a buried insulating film 126. Afterwards, the second mask pattern M2 remaining on the substrate 110 may be removed, and the buried insulating film 126 and the insulating thin film 114 may be planarized so that the top surface 110T of the substrate 110 may be exposed.

According to the method of manufacturing the IC device 100, which has been described with reference to FIGS. 10A to 10J, before the device isolation trench 112T and the interface trench 312T are filled by the device isolation structure 112 and the interface isolation structure 312, the deposition inhibition film 113 may be thinly coated on an upper portion of the plurality of cell active regions A1 and on an upper portion of the peripheral circuit active region A2. Thus, during a subsequent process of forming the etching induction film 112A, the etching induction film 112A may selectively fill only a lower portion of each of the device isolation trench 112T and the interface trench 312T. In some example embodiments, the etching induction film 112A may be etched at a higher etch rate than not only the substrate 110 but also the insulating liner 112B and the gap-fill insulating film 112C, and thus, a saddle fin portion SF having an increased height may be formed during the formation of the word line trench 120T. As the height of the saddle fin portion SF is increased, an area of the portion of the cell active region A1 facing the word line 124 with the gate dielectric film 122 therebetween may be increased, and reliability of the IC device 100a may be improved.

While the inventive concept has been particularly shown and described with reference to some example embodiments thereof, it will be understood that various changes in form and details may be made therein without departing from the spirit and scope of the following claims.

What is claimed is:

1. An integrated circuit device comprising:
a substrate having a plurality of active regions defined by a device isolation trench;
a device isolation structure including an etching induction film and filling the device isolation trench;
the etching induction film covering a bottom surface of the device isolation trench;
a word line trench intersecting with the plurality of active regions and the device isolation structure and extending in a first lateral direction;
a gate dielectric film covering an inner wall of the word line trench; and
a word line filling a portion of the word line trench on the gate dielectric film,
wherein each of the plurality of active regions comprises a fin body portion under the word line and a saddle fin portion protruding from the fin body portion toward the word line, and
at least a portion of the etching induction film is exposed by the word line trench.

2. The integrated circuit device of claim 1, wherein
the device isolation structure has an overlap area overlapping the word line in a vertical direction,
the overlap area comprises,
a first region between a first active region and a second active region adjacent to the first active region in the first lateral direction, the first active region and the second active region being selected from the plurality of active regions, and
a second region between the first active region and a third active region adjacent to the first active region in the first lateral direction, the first active region and the third active region being selected from the plurality of active regions, the third active region facing the second active region with the first active region therebetween in the first lateral direction, and
the device isolation structure of the first region comprises the etching induction film.

3. The integrated circuit device of claim 2, wherein
the device isolation structure has a first top surface in the first region and has a second top surface in the second region, and
the first top surface is at a same level as the second top surface in the vertical direction.

4. The integrated circuit device of claim 2, wherein
the device isolation structure has a first top surface in the first region and has a second top surface in the second region, and
the first top surface is at a lower level than the second top surface in the vertical direction.

5. The integrated circuit device of claim 2, wherein the second region of the device isolation structure comprises:
an insulating liner covering a top surface of the etching induction film and an inner wall of the device isolation trench; and
a gap-fill insulating film filling the device isolation trench on the insulating liner.

6. The integrated circuit device of claim 1, wherein
the word line trench comprises a first bottom surface at which the saddle fin portion is exposed and a second bottom surface at which the device isolation structure is exposed, and
a top of the first bottom surface is at a higher level than a top of the second bottom surface in a vertical direction.

7. The integrated circuit device of claim 1, wherein
the word line trench comprises a first bottom surface at which the saddle fin portion is exposed and a second bottom surface at which the device isolation structure is exposed, and
the portion of the etching induction film is exposed through the second bottom surface.

8. The integrated circuit device of claim 1, wherein
the fin body portion has a first height in a vertical direction,
the saddle fin portion has a second height in the vertical direction, and
a ratio of the second height to the first height is 0.2 or higher.

9. The integrated circuit device of claim 1, wherein the etching induction film comprises silicon oxide doped with fluorine (F).

10. The integrated circuit device of claim 8, wherein
the etching induction film has a first oxygen content and a first fluorine content,
the first oxygen content is 66 at % or less, based on a total element content of the etching induction film, and
the first fluorine content is 14 at % or less, based on the total element content of the etching induction film.

11. An integrated circuit device comprising:
a substrate having a plurality of active regions defined by a device isolation trench;
a device isolation structure including an etching induction film and filling the device isolation trench, the etching induction film covering a bottom surface of the device isolation trench; and
a word line in a word line trench, the word line trench intersecting with the plurality of active regions and the device isolation structure and extending in a first lateral direction,
wherein the device isolation structure has an overlap area overlapping the word line in a vertical direction, and the overlap area comprising,
a first region between a first active region and a second active region adjacent to the first active region in the first lateral direction, the first active region and the second active region being selected from the plurality of active regions, and
a second region between the first active region and a third active region adjacent to the first active region in the first lateral direction, the first active region and the third active region being selected from the plurality of active regions, the third active region facing the second active region with the first active region therebetween in the first lateral direction, and
wherein the etching induction film is exposed through the word line trench in the first region and covers the bottom surface and a lower inner wall of the device isolation trench in the second region.

12. The integrated circuit device of claim 11, wherein
the device isolation structure has a first top surface in the first region and has a second top surface in the second region, and
the first top surface is at a lower level than the second top surface in the vertical direction.

13. The integrated circuit device of claim 11, wherein
the device isolation structure has a first top surface in the first region and has a second top surface in the second region, and
the first top surface is at a same level as the second top surface in the vertical direction.

14. The integrated circuit device of claim 11, wherein
each of the plurality of active regions comprises a fin body portion under the word line and a saddle fin portion protruding from the fin body portion toward the word line,
the word line trench comprises a first bottom surface at which the saddle fin portion is exposed and a second bottom surface at which the device isolation structure is exposed, and
a top of the first bottom surface is at a higher level than a top of the second bottom surface in the vertical direction.

15. The integrated circuit device of claim 11, wherein
each of the plurality of active regions comprises a fin body portion under the word line and a saddle fin portion protruding from the fin body portion toward the word line,
the fin body portion has a first height in the vertical direction,
the saddle fin portion has a second height in the vertical direction, and
a ratio of the second height to the first height is 0.2 or higher.

16. The integrated circuit device of claim 11, wherein the etching induction film comprises silicon oxide doped with fluorine (F).

17. An integrated circuit device comprising:
a substrate having a cell array region, a peripheral circuit region, and an interface region between the cell array region and the peripheral circuit region;
a plurality of cell active regions defined by a device isolation trench in the cell array region;
a peripheral circuit active region defined by an interface trench in the peripheral circuit region;
a device isolation structure including an etching induction film and filling the device isolation trench;
the etching induction film covering a bottom surface of the device isolation trench in the cell array region;
an interface isolation structure filling the interface trench in the peripheral circuit region;
a word line trench intersecting with the plurality of cell active regions and the device isolation structure in the cell array region and extending in a first lateral direction, the word line trench having a first bottom surface exposing the plurality of cell active regions and a second bottom surface exposing the device isolation structure;
a gate dielectric film covering an inner wall of the word line trench; and
a word line filling a portion of the word line trench on the gate dielectric film,
wherein a portion of the etching induction film is exposed through the second bottom surface.

18. The integrated circuit device of claim 17, wherein each of the plurality of cell active regions comprises a fin body portion under the word line and a saddle fin portion protruding from the fin body portion toward the word line.

19. The integrated circuit device of claim 17, further comprising:
a deposition inhibition film covering an upper sidewall of the peripheral circuit active region.

20. The integrated circuit device of claim 19, wherein the deposition inhibition film comprises nitrogen (N₂), nitrogen trifluoride (NF₃), ammonia (NH₃) or a combination thereof.
